(19) United States
(12) Patent Application Publication
(10) Pub. No.: US 2024/0145189 A1
(43) Pub. Date: May 2, 2024

(54) INTERRUPTER CIRCUIT WITH DIAGNOSTIC CIRCUIT

(71) Applicant: ABBERIOR INSTRUMENTS GMBH, Goettingen (DE)

(72) Inventor: Lars KASTRUP, Goettingen (DE)

(21) Appl. No.: 18/376,947

(22) Filed: Oct. 5, 2023

(30) Foreign Application Priority Data
Oct. 27, 2022 (DE) 10 2022 128 577.4

(51) Int. Cl. H01H 9/54; H01H 33/59; H01H 47/00

(52) U.S. Cl. CPC H01H 9/542; H01H 33/596; H01H 47/002

(57) ABSTRACT

The invention relates to an interrupter circuit 1 comprising a diagnostic circuit 5 for monitoring the switching state of a plurality of switching elements 3, 4 connected in series. The interrupter circuit 1 is used in particular in the context of safety devices for switching off electrical equipment, in particular electrical drives and lasers.

### CROSS-REFERENCE TO RELATED APPLICATIONS

The present application claims the benefit of and priority to DE Patent Application Serial No. 10 2022 128 577.4, filed Oct. 27, 2022, the entire contents of which is incorporated herein by reference.

### TECHNICAL FIELD OF THE INVENTION

The present invention relates to an interrupter circuit comprising a diagnostic circuit for the functional safety of an electrical or electronic circuit performing a safety function. In particular, the interrupter circuit relates to safety-critical shutdown devices of electric drives and/or lasers.

### PRIOR ART

Due to its principle, electrical equipment (machines, electrical devices, electrical tools, lasers) pose hazards to the operator or user that must be minimized and reduced to an acceptable level by organizational and technical measures. The hazards include mechanical hazards due to moving machine parts or tools and thermal hazards due to hot or cryogenic devices or work equipment in the work area. Finally, due to the increasing use of lasers with high optical laser powers, hazards caused by laser radiation must also be increasingly taken into account. Hazards due to laser radiation also arise when using laser-based measuring instruments, for example when using laser scanning microscopes in research and development.

An essential measure to control hazards from running machines or lasers is an automatic shutdown as soon as the machine or device is in an unsafe condition, i.e., the operator has access to the hazardous area or laser radiation can escape. For this purpose, the accesses to the hazardous area (doors, flaps, inspection openings, etc.) are equipped with sensors that are connected to a shutdown device that puts the machine in a safe state when the monitored accesses is opened and, in particular, switches off electrical drives or laser sources.

To ensure that the shutdown device is sufficiently fail-safe to meet the requirements of functional safety, all sensors, signal paths, logical linking units and actuators are regularly designed with redundancy.

Among the sensors and the actuators for switching off the electrical equipment, switching elements such as mechanical switches or switching relays can be connected in series to realize redundancy. In this way, the safety function continues to function even if a switching element fails (for example, upon welding of a switching contact), and the safety of the system remains guaranteed. Although such a failure of one switching element causes the safety function to continue to be performed by the redundant second switching element, the failure of the one switching element remains undetected without further measures. For this reason, the relevant standards (e.g., series of standards DIN EN 61508 Functional safety, DIN EN 62061 Safety of machinery) provide for diagnostic functions with which the switching state of the switching elements can be monitored and checked for consistency.

Such a diagnostic function can be realized for a single switching element by measuring the voltage drop across the switching element itself or across a small resistor connected in series: When the switching element is closed, both terminals are shorted and no voltage drop occurs across the switching element. In the open state, on the other hand, the (supply) voltage of the load to be switched is present across the switching element. The reverse is true for a series-connected resistor: if a current flows in the circuit, a (small) measurable voltage drops across the resistor, whereas if the circuit is open, no current flows and accordingly no voltage drops across the resistor. Thus, the switching state of the switching element can be inferred from a voltage measurement.

Mechanical switching elements especially for safety applications are usually configured with a pair of switches, wherein the switches are mechanically coupled and can only move together (force-guided contacts). In this case, one switch performs the actual safety function/switch-off function, while the second switch is part of a diagnostic circuit used to monitor the switching state of the switching element. One advantage of using such switching elements is that the diagnostic circuit is electrically isolated from the main circuit. This type of switching state monitoring works independently of the voltages and currents in the switched circuit and also when several switching elements are connected in series.

On the other hand, the failure rate of mechanical switching elements and in particular of mechanical relays is greater than that of semiconductor-based switches (solid-state relays) due to their design, which thus have significant advantages with regard to the requirements for fail-safe operation.

However, a concept of monitoring the switching state corresponding to force-guided contacts cannot be applied to semiconductor switches, so the diagnostic circuit must be implemented in a different way. Monitoring the voltage drop across the switching element can also be used here, but this approach fails when several switching elements are connected in series: In this case, the voltage drop of a switching element depends not only on its own switching state but also on that of the other switching element, so that independent monitoring of both switching elements is not possible.

### Objective of the Invention

The present invention therefore has the objective of specifying an interrupter circuit with a diagnostic function, with which it is possible to determine and monitor the switching state of a plurality of series-connected switching elements independently of one another.

### Solution

This objective is attained by the interrupter circuit according to independent claim 1. Claims 2 to 10 relate to preferred embodiments of the interrupter circuit, while independent claim 11 specifies a laser scanning microscope with an interrupter circuit according to one of the claims 1 to 10. Independent claim 12 relates to a method for monitoring the switching states of a plurality of series-connected switching elements in an interrupter circuit.

### DESCRIPTION OF THE INVENTION

The invention is based on the idea of implementing the monitoring of the switching state of a switching element with a separately generated monitor signal that is coupled into the circuit to be switched, wherein the monitor signal is coupled into the circuit on one side of the switching element to be monitored and tapped at a probe point on the other side of the switching element. To this end, the invention builds on the circuit principle proposed by J. Truchsess in “Simple Circuit Communicates Over Low-Voltage Power Lines,” https://www.electronicdesign.com/print/content/21799727 (Apr. 15, 2013), for transmitting data over a power supply line. Therein, a modulated carrier signal is modulated onto the supply voltage in the transmitter, while in the receiver the modulated carrier signal is separated from the supply voltage via a high-pass filter, demodulated, and decoded.

One aspect of the invention relates to an interrupter circuit with a diagnostic circuit for monitoring the switching states of two series-connected switching elements that interrupt or close a useful signal in an electrical circuit. The useful signal may be, in particular, a supply voltage of an electrical operating means, especially of an electrical drive or of a laser. However, the useful signal may also be an analog or digital control signal that is used to control the shutdown of an electrical device.

The switching elements are, in particular, mechanically or magnetically operated switches or pushbuttons, reed contacts, mechanical relays, contactors, or semiconductor switches such as transistors, field-effect transistors, phototransistors, photo-thyristors, photo-triacs, opto couplers, photo-relays, semiconductor relays, or Hall sensors.

The diagnostic circuit of the interrupter circuit comprises a signal source which generates a monitor signal which is coupled into the circuit at a feed point between the two series-connected switching elements and propagates in the circuit together with the useful signal from the feed point. In a simple embodiment, the signal source is configured as a pulse generator, which generates a sequence of (square) pulses as a monitor signal, or as a harmonic oscillator, which generates a sinusoidal AC voltage as a monitor signal.

The monitor signal may be coupled into the circuit, for example, by capacitive coupling with a coupling capacitor acting as a high-pass filter. If the useful signal is a supply voltage (DC voltage or AC voltage with a common mains frequency of 50-60 Hz), a periodic signal with a frequency in the kilohertz range or higher may be used as the monitor signal. In the rarer application case that the useful signal exclusively comprises high frequencies, a low-frequency or even a DC voltage signal may be selected as the monitor signal, which is coupled into the circuit via a low-pass filter.

According to the invention, the diagnostic circuit of the interrupter circuit comprises at least two probe points, at each of which a probe signal is tapped from the circuit. The probe points are arranged in such a way that a switching element is located in the circuit between a probe point and the feed point in each case, so that the monitor signal is switched together with the useful signal by this switching element. Thus, depending on the switching state of the switching element, the monitor signal does propagate in the circuit (switching element closed) or does not (switching element open). The monitor signal extracted from the probe signal (i.e., separated from the useful signal) can therefore be used to infer the switching state of the switching element. For the separation of the monitor signal from the probe signal, a high-pass filter may be used if the frequency of the monitor signal is above the frequency of the useful signal, or a low-pass filter if the frequency of the monitor signal is below the frequency of the useful signal.

The extracted monitor signal is processed in a downstream detector circuit to generate a (preferably digital) status signal that can be used for subsequent consistency checks, etc. For signal processing, it may be sufficient to detect the presence or absence of the monitor signal. If the monitor signal is designed as a sequence of (square) pulses, the detector circuit may be designed in the form of a post-triggerable, monostable toggle stage (monoflop) which is triggered by successive pulses of the monitor signal and which resets after a preset or adjustable hold time if the pulses fail to appear. For this purpose, the hold time of the toggle stage must correspond at least to the pulse-to-pulse interval. If the response time required by the application permits, the noise immunity to individual undetected pulses may be increased by selecting the hold time to be somewhat longer (e.g., as a small multiple of the pulse-to-pulse interval).

Alternatively, the monitor signal may be detected by smoothing it with a low-pass filter after separation from the probe signal and comparing it with a comparator against a reference level. Here, the cutoff frequency of the low-pass filter determines the response time of the detector. This type of detection may also be used for sinusoidal monitor signals, wherein the half-waves must first be rectified before low-pass filtering.

To facilitate the separation of the monitor signal from the useful signal, in a preferred embodiment of the diagnostic circuit the frequency of the monitor signal is selected to be at least a factor of 10 higher than an upper cutoff frequency or at least a factor of 10 lower than a lower cutoff frequency of the useful signal.

If the circuit is closed by the two switching elements, the monitor signal also propagates to the other parts of the circuit, where they may possibly cause malfunctions. For this reason, in a preferred embodiment, the monitor signal is implemented as a periodic signal with a small amplitude, which is not more than 10%, preferably not more than 5%, particularly preferably not more than 2% of the useful signal.

As a further measure against possible malfunctions in the circuit caused by the monitor signal, in a further preferred embodiment the interrupter circuit comprises a blocking filter between each of the terminals of the circuit and the probe points, which suppresses the monitor signal by at least 10 dB, preferably by at least 20 dB, particularly preferably by at least 30 dB. Such blocking filters are extensively known from the prior art, and the skilled person may, for example, use established filter designs (e.g., Butterworth filters, Chebyshev filters, Bessel filters) or commercially available filter components.

The reliability of the diagnostic circuit may be impaired if it is operated in an environment with sources of interference that use similar periodic signals as the diagnostic circuit. These interference sources may be external and cause interference by radiating into the diagnostic circuit. However, interference sources may also be components that are part of the circuitry comprising the interrupter circuit. For example, DC/DC voltage converters contained in many power supplies operate with internal frequency generators whose switching frequencies are in the range of a few 100 kilohertz and may be a source of interference.

One measure for improving the immunity of the diagnostic circuit to such interference sources may be to modulate the strictly periodic monitor signal and thus give it a characteristic that allows the monitor signal to be distinguished from other (periodic) interference signals. For this purpose, in one embodiment of the diagnostic circuit, the monitor signal is amplitude-, frequency- or phase-modulated in the signal source and demodulated again in the signal conditioning circuit. For the modulation of the monitor signal, for the demodulation and, if necessary, for the restoration of the data from the demodulated probe signal, the skilled person may make use of established procedures from communications engineering.

In one variant of this embodiment of the diagnostic circuit, the modulation of the monitor signal is used to transmit data between the feed point and the probe points. The data may, in particular, be an identifier which can be used to uniquely identify the signal source in the circuit. The identification of the signal source is particularly important if the diagnostic circuit comprises further signal sources which must be distinguished from one another.

A preferred embodiment of the diagnostic circuit is characterized in that the diagnostic circuit comprises a comparator that compares the status signal of one of the switching elements with the control signal of the same switching element and generates an error signal at its output. On a logical level, this corresponds to an exclusive-or (XOR) operation.

The error signal makes it possible to detect the loss of integrity of the circuit even in error states in which the proper function of the series-connected switching elements is maintained if only one of the switching elements fails and the error cannot be detected without a diagnostic circuit. This situation occurs, for example, when a switching element remains permanently closed regardless of the control signal, as can occur, for example, due to electrical overload in mechanical relays (welding of the switching contacts) or in semiconductor switching elements.

If the switching elements are actuated together or receive a common control signal, the diagnostic circuit may alternatively or additionally comprise a (further) comparator which compares the status signal of one switching element with the status signal of the other switching element and generates an error signal if the status signals differ.

The error signal may be used to set the monitored system to a safe state. For this purpose, the interrupter circuit may comprise a third switching element connected in series with the first and the second switching element, which interrupts the circuit as soon as one of the comparators detects a deviation of the status signal of the first or the second switching element from the respective control signal or, if the switching elements receive a common control signal, a deviation between the status signals of the switching elements.

Instead of connecting a third switching element in series with the first and second switching elements and breaking the circuit when a fault condition is detected, a system may also be set into a safe condition by an additional safety device. For example, a machine for laser material processing or a laser scanning microscope potentially poses a hazard due to escaping laser light. Here, on the one hand, the emission of laser light can be blocked with a shutter at an emission aperture; on the other hand, a shutdown device can additionally be provided in the voltage supply of the laser light source. In particular, if frequent switching off of the laser during regular operation is undesirable (because this impairs the service life of the laser or leads to thermal instabilities, for example), the laser beam can be unblocked during regular operation by means of a shutter controlled by an interrupter circuit according to the invention. Only if the diagnostic circuit detects an error condition, the laser light source is switched off via a switching element in the power supply controlled by the error signal of the diagnostic circuit.

Alternatively or additionally, the error signal may also be used to indicate an error condition to the operator, so that the operator is enabled to shut down the system if necessary and/or to initiate a repair of the system before a dangerous situation can occur as a result of a further error.

The described concept of the interrupter circuit can be extended to interrupter circuits comprising further switching elements to increase the degree of redundancy. In this embodiment, the interrupter circuit comprises at least one further feed point arranged between the switching elements for feeding in at least one further monitor signal and at least one further probe point for tapping at least one further probe signal, the feed and probe points preferably being arranged alternately between the switching elements.

In this embodiment of the interrupter circuit, it is necessary for the monitor signals of the included diagnostic circuit to be distinguishable from one another so that the status signals generated by the detector circuits can be assigned to a switching element. Differentiation of the monitor signals can be achieved, for example, by using different frequencies and with (bandpass) filters tuned to these frequencies before signal processing.

A distinction can also be made in that the monitor signals are carriers of information, in particular a unique identifier. For this purpose, identifiers may be modulated onto the monitor signals in analog form (for example as different frequencies), or digital data comprising a corresponding unique identifier may be transmitted from the feed point to the probe point using a data transmission protocol based on the monitor signal as carrier signal. The use of a data transmission protocol also enables the implementation of an error correction, in particular a check sum, which can be used to further improve the immunity of the diagnostic circuit to interference.

A second aspect of the invention relates to a laser scanning microscope, characterized in that the laser scanning microscope comprises a laser safety device comprising an interrupter circuit in accordance with the invention. The laser safety device in such a laser scanning microscope serves to prevent operating conditions in which laser radiation can escape and lead to a hazard for the user. In accordance with laser safety regulations, it is typically controlled by sensors that monitor the condition of access points to the laser scanning microscope or light paths within the laser scanning microscope. Furthermore, the laser shutdown is usually controlled by a key switch to prevent unauthorized operation. A suitable logical combination of the sensor states and the key switch generates a control signal that causes the laser sources to be turned off via switching elements of the laser shutdown device. The design of the laser shutdown device in the form of an interrupter circuit according to the invention makes it possible to meet the requirements for the safety integrity of the laser shutdown device.

A third aspect of the invention relates to a method for independently monitoring the switching states of a first and a second series-connected switching element, wherein the switching elements are used to interrupt a useful signal in an electrical circuit.

According to the invention, a monitor signal is generated and coupled into the circuit at a feed point between the switching elements. The type and design of the monitor signal are described in the description of the interrupter circuit.

The method further comprises tapping probe signals at a first and a second probe point, the probe points being arranged such that the first switching element is located in the circuit between the first probe point and the feed point and the second switching element is located between the second probe point and the feed point.

The method further comprises separating the monitor signal from the probe signals with filters, wherein a separate filter is provided for each probe signal.

The method lastly comprises generating a first status signal representing the switching state of the first switching element and a second status signal representing the switching state of the second switching element from the respective separated monitor signal.

Further advantageous embodiments of the invention result from the claims, the description and the drawings and the associated explanations to the drawings. The described advantages of features and/or combinations of features of the invention are merely exemplary and may have an alternative or cumulative effect. With regard to the scope of disclosure (but not the scope of protection) of this patent application and the patent, the following applies: Further features can be found in the drawings—in particular the relative arrangements and effective combinations shown.

The combination of features of different embodiments of the invention or of features of different claims is also possible in deviation from the selected back relationships of the claims and is hereby suggested. This also applies to such features which are shown in separate drawings or are mentioned in the description thereof. These features can also be combined with features of different claims. Likewise, features listed in the claims may be omitted for further embodiments of the invention, but this does not apply to the independent claims of the granted patent.

The reference signs contained in the claims do not represent a limitation of the scope of the objects protected by the claims. They merely serve the purpose of making the claims easier to understand.

### BRIEF DESCRIPTION OF THE FIGURES

FIG. 1 shows the basic form of the interrupter circuit according to the invention.

FIG. 2 shows an embodiment of the interrupter circuit according to the invention with a consistency check.

FIG. 3 shows a laser shutdown device with a interrupter circuit according to the invention.

FIG. 4 shows a interrupter circuit with four switching elements connected in series.

FIG. 5 shows a coding scheme that can be used to code a monitor signal with different identifiers.

FIG. 6 shows a laser scanning microscope according to the invention with an interrupter circuit as a laser safety device.

### DESCRIPTION OF THE FIGURES

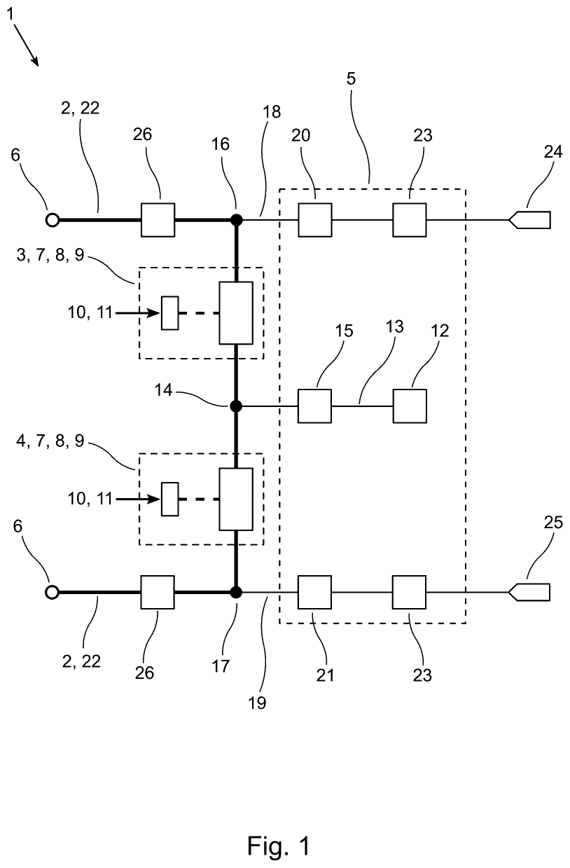

FIG. 1 shows an interrupter circuit 1 according to the invention in a circuit 2 (shown with a wide line) comprising two switching elements 3, 4 connected in series, with which the circuit 2 can be closed or interrupted, the switching states of the switching elements 3, 4 being monitored with a diagnostic circuit 5. The interrupter circuit 1 is integrated into the circuit 2 (otherwise not shown) via the terminals 6. The switching elements 3, 4 may be designed in particular as mechanical switches or as pushbuttons 7, as mechanical switching elements (e.g., relays or contactors 8, magnetically actuated reed contacts) or as semiconductor switches 9 (e.g., transistors, field-effect transistors, phototransistors, photo-thyristors, photo-triacs, opto couplers, semiconductor relays, Hall sensors). The actuation of the switching elements 3, 4 depends on their embodiment and may be performed accordingly by a mechanical trigger 10 or by an electrical, optical or magnetic control signal 11.

As shown in the figure, the switching elements 3, 4 can be triggered separately—also by different triggers 10 or control signals 11; however, both switching elements 3, 4 may also be actuated by a common trigger 10 or a common control signal 11.

According to the invention, the diagnostic circuit 5 of the interrupter circuit 1 comprises a signal source 12 which generates a monitor signal 13 which is coupled into the circuit 2 at the feed point 14 via a coupler 15. The signal source 12 may be, for example, a square wave or a sine wave generator. Optionally, the signal source 12 may also comprise an encoder (not shown) which encodes information, in particular a unique identifier, into the monitor signal 13.

At contacts of the switching elements 3, 4 opposite the feed point 14, probe signals 18, 19 are tapped at probe points 16, 17 and fed to filters 20, 21, which separate the monitor signal 13 from a useful signal 22 of the circuit 2. In the detector circuits 23, a first status signal 24 is generated from the filtered first probe signal 18 and a second status signal 25 is generated from the second filtered probe signal 19, which represent the switching states of the respective switching elements 3, 4. In the simplest case, the function of the detector circuits 23 is merely to check whether the levels of the monitor signals 13 separated from the probe signals 18, 19 exceed a threshold value. However, the detector circuits 23 may also include decoding of information transmitted with the monitor signal 13 from the signal source 12, in particular an identifier.

To prevent the monitor signal 13 from propagating into the rest of the circuit 2, blocking filters 26 are provided between the terminals 6 and the probe points 16, 17 to inhibit the monitor signal 13. These blocking filters 26 are optional and can be omitted if interference of the useful signal 22 by the monitor signal 13 can be excluded.

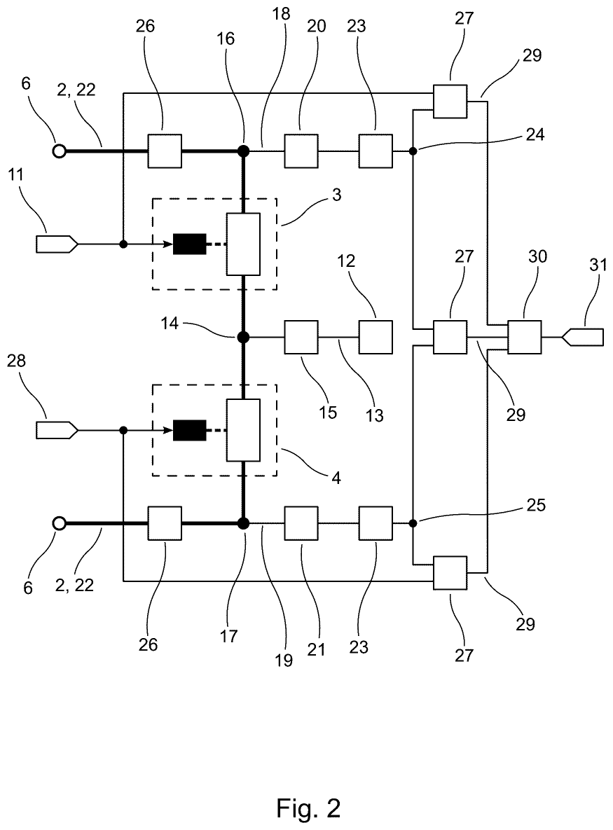

The embodiment of the interrupter circuit 1 shown in FIG. 2 corresponds to the circuit shown in FIG. 1, but is extended by comparators 27, with which a consistency check of the switching states of the switching elements 3, 4 is carried out. The comparators 27 perform a logical exclusive-OR (XOR) operation between the status signals 24, 25 among each other or between the control signal 11 and the status signal 24 or between the control signal 28 and the status signal 25 and, in the event of a discrepancy, output an error signal 29 at their output which enables the error state to be assigned to the respective switching element 3 or 4. If the switching elements 3, 4 are controlled with a common control signal 10, i.e. the control signals 11 and 28 are identical, the comparison of the switching state of one of the switching elements 3, 4 with the control signal 11 may also be omitted without loss of a diagnostic circuit.

In the embodiment shown, the outputs of the comparators 27 are additionally combined with an OR gate 30 to form an error signal 31 for the overall circuit. This aggregated error signal 31 can be used to control an additional shutdown device (not shown).

Although the filters 20, 21, the detector circuits 23, the comparators 27, and the OR gate 30 are shown here as logically separate functional units, it should be emphasized that in practice these functionalities need not be performed separately at all but are usually integrated in one circuit.

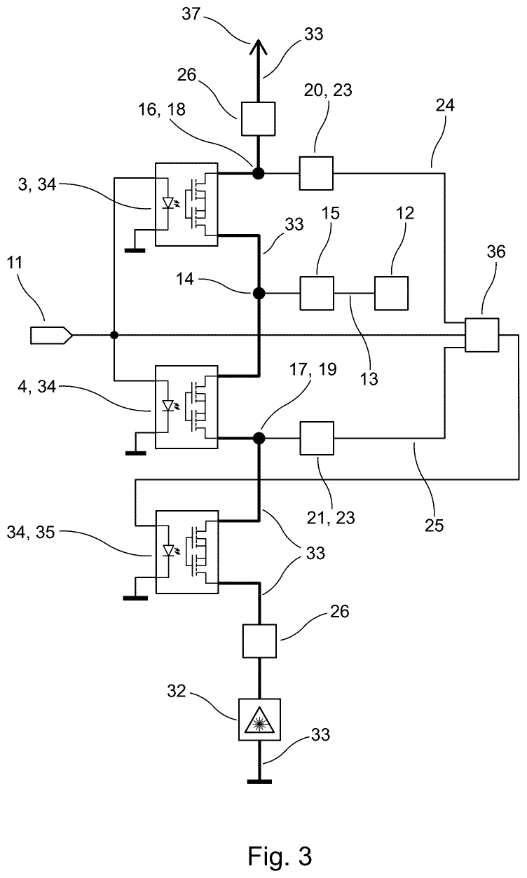

FIG. 3 shows the use of the interrupter circuit in a shutdown device for a laser 32, wherein the shutdown device may be part of a laser interlock system, for example in a machine or a laser scanning microscope. The interrupter circuit corresponds to the embodiment shown in FIG. 2, wherein the switching elements 3, 4 are inserted into the supply circuit 33 (wide line width) of the laser 32 and are designed as semiconductor relays 34. In addition, a further switching element 35, also designed as a semiconductor relay 34, is connected in series with the first switching element 3 and the second switching element 4 here for an (emergency) shutdown of the laser 32. The further switching element 35 is controlled by a consistency checker 36 which compares the first status signal 24, the second status signal 25 and the control signal 11 with each other and, if an inconsistency occurs, opens the switching element 35, thus disconnecting the laser 32 from the voltage source 37. The filters 20, 21 for separating the monitor signal 13 from the probe signals 18, 19 and the detector circuits 23 are shown here as integrated functional units.

Blocking filters 26 are arranged in the supply circuit 33 to both the voltage source 37 and the laser 32 to prevent the monitor signal 13 from interfering with the voltage source 37 or the laser 32.

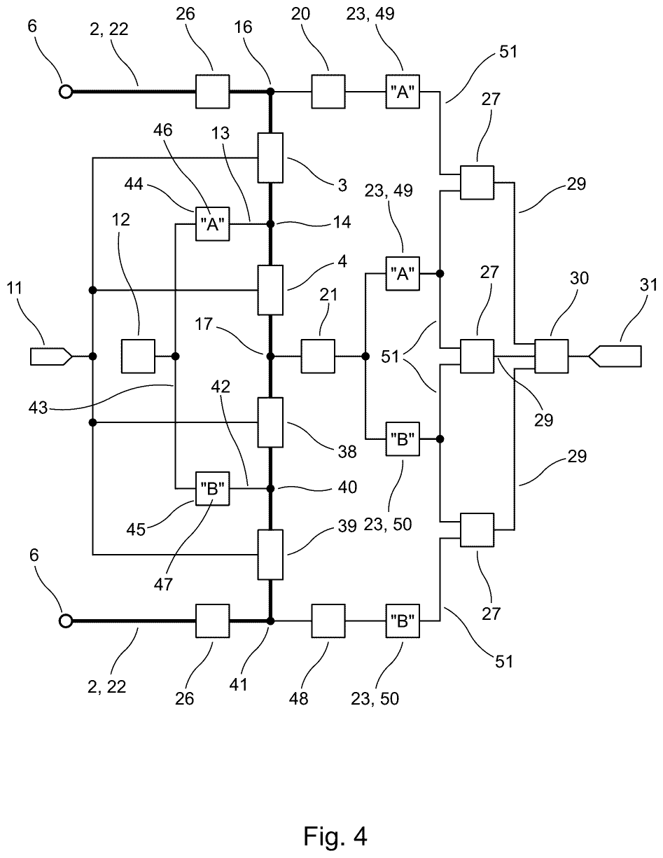

FIG. 4 shows an extension of the interrupter circuit according to the invention to more than two switching elements. Specifically, four series-connected switching elements 3, 4, 38, 39 are inserted into circuit 2 via terminals 6, with the switching elements 3, 4, 38, 39 being controlled by a common control signal 11. The circuit 2 is again protected by blocking filters 26 against propagation of the monitor signals 13, 42 from the diagnostic circuit.

For individual monitoring of the four switching elements 3, 4, 38, 39, feed points 14, 40 and probe points 16, 17, 41 are arranged alternately between the switching elements, with distinguishable monitor signals 13, 42 being coupled into the circuit 2 at the feed points 14, 40. In the embodiment of the diagnostic circuit shown, the distinguishable monitor signals 13, 42 are generated on the basis of the carrier signal 43 of a common signal source 12 by means of two encoders 44, 45, which encode two unique identifiers 46, 47, herein designated as “A” and “B”, respectively, into the carrier signal 43.

As in the previously shown embodiments, the monitor signals 13, 42 are separated from the useful signal 22 of the circuit 2 at the probe points 16, 17, 41 by means of filters 20, 21, 48. The subsequent detector circuits 23 additionally contain decoders 49, 50 which extract the identifiers 46, 47 encoded with the encoders 44, 45 from the monitor signals 13, 42. On the basis of these identifiers 46, 47, it is possible to infer the feed point 14, 40 of the monitor signal 13 or 42 and thus the switching state of the switching element 3, 4, 38, 39 arranged in each case between the feed point 14, 40 and the probe point 16, 17, 41. For example, a monitor signal 13 detected at the probe point 16 which carries the identifier “A” 46 indicates a closed switching element 3, while the absence of a monitor signal 13 with the identifier “A” 46 at the probe point 16 indicates an open switching state of this switching element 3. Accordingly, the switching state of the switching element 4 can be inferred from the monitor signal 13 with the identifier “A” 46 as detected at the probe point 17, the switching state of the switching element 38 can be inferred from the monitor signal 42 with the identifier “B” 47 as detected at the probe point 17, and the switching state of the switching element 39 can be inferred from the monitor signal 42 with the identifier “B” 47 as detected at the probe point 41.

The status signals 51 at the outputs of the detector circuits 23 are again monitored by comparators 27 for any discrepancies from each other, and an OR gate 30 is used to combine the error signals 29 into an aggregate error signal 31 of the circuit.

Optionally, the diagnostic circuit may be extended by a comparator (not shown), which additionally compares one of the status signals with the control signal and thus completes the monitoring.

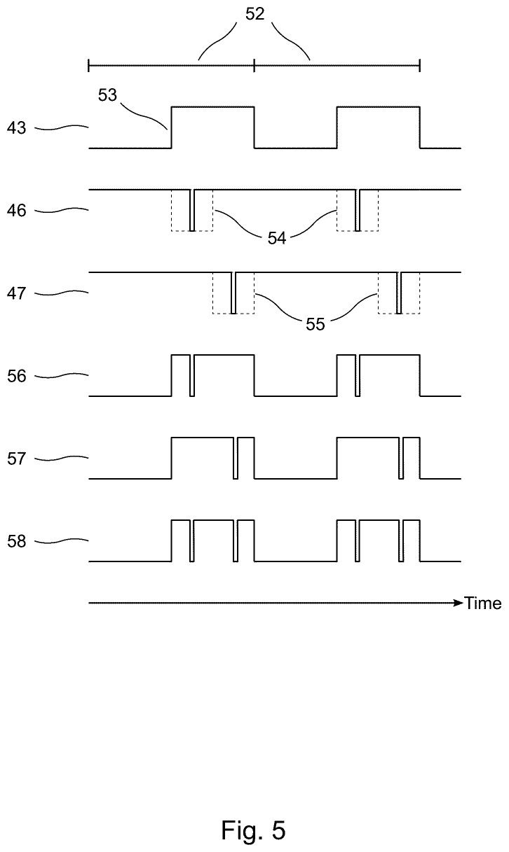

FIG. 5 shows an example of a simple coding scheme that can be used to code the monitor signals for the interrupter circuit shown in FIG. 4 with two different identifiers 46, 47. The coding scheme is based on a digital carrier signal 43 with a duty cycle of 1:1. The identifiers are transmitted once with each period 52 of the carrier signal 43, each transmission starting with the rising edge 53 of the carrier signal 43. For this purpose, the subsequent phase in which the carrier signal has a HIGH level is divided into a first time window 54 and a second time window 55, the first time window 54 being assigned to the identifier “A” 46 and the second time window 55 being assigned to the identifier “B” 47. In order to code the carrier signal 43 with the identifier “A” 46, the encoder 44 briefly pulls the carrier signal 43 to a LOW level within the first time window 54; correspondingly, the encoder 45 for the identifier “B” 47 briefly pulls the carrier signal 43 to a LOW level within the second time window 55. Technically, such an encoding scheme can be realized by logically ANDing the carrier signal and the identification signals, for example with a square-wave generator and encoders that are interconnected by open collector or open drain circuitry.

Track 56 shows the monitor signal 13 in which the identifier “A” 46 is encoded within the first time window 54, track 57 shows a corresponding monitor signal 42 which carries the identifier “B” 47 in the second time window 55. The decoders 49, 50 of the interrupt circuit shown in FIG. 4 can detect these short intervals with LOW level and reconstruct the respective identifier 46 or 47 by a temporal assignment to the time windows 54, 55.

For example, if a short interval with LOW level is detected in the first time window 54 in the probe signal tapped at probe point 16 (FIG. 4), this indicates that the switching element 3 is closed. Accordingly, a short interval with LOW level in the first time window 54 in the probe signal tapped at probe point 17 indicates that the switching element 4 is closed. If the switching element 38 shown in FIG. 4 is also closed, the monitor signal 42 with the identifier “B” 47 also propagates from the feed point 40 to the probe point 17, so that the probe signal tapped there carries both identifiers “A” 46 and “B” 47 and has a curve corresponding to the track 58.

An extension of the described coding scheme to more than two identifiers can be realized, for example, by dividing the HIGH half-period of the carrier signal into more than two time windows.

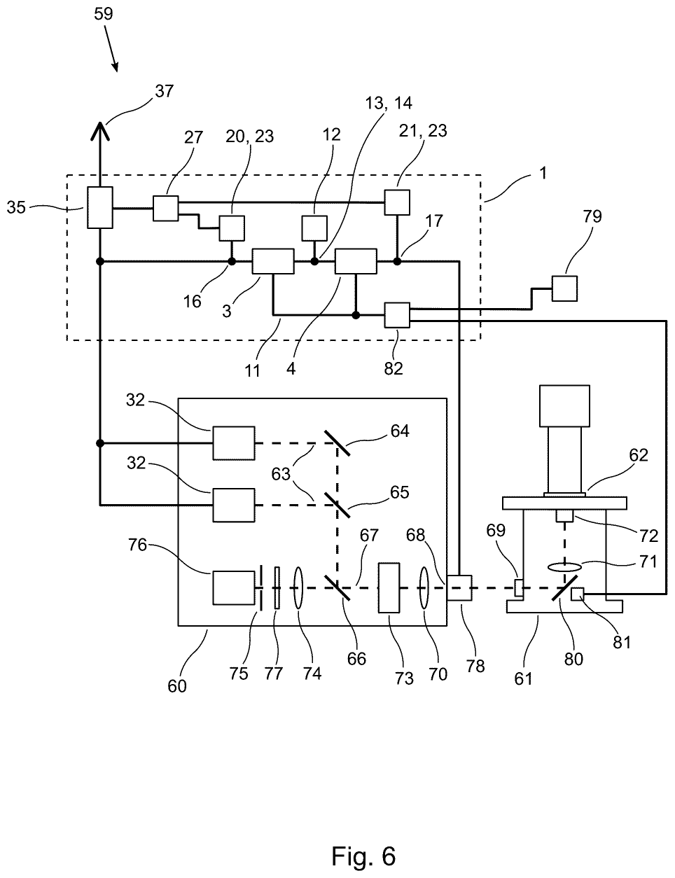

FIG. 6 shows a laser scanning microscope 59 according to the invention with a laser scanning unit 60, a microscope stand 61 and a laser safety device comprising an interrupter circuit 1 according to the invention. The laser scanning unit 60 is designed as a confocal laser scanning unit and comprises two lasers 32 as light sources, which provide illumination light for exciting fluorescence in the sample 62. The laser beams 63 are combined with a mirror 64 and a beam splitter 65 and coupled into the main beam path 67 via another beam splitter 66. The laser light passes through the exit port 68 and into the microscope stand 61 through the light port 69.

By means of a scan lens 70 and a tube lens 71, the laser beams 63 are imaged into the rear aperture of the objective 72, which focuses the laser beams 63 into the sample 62. The position of the focus in the sample 62 can be shifted with a scanner 73 located in the main beam path 67 to capture a raster image by scanning the sample 62 with the laser light. Fluorescence light generated in the sample 62 and collected by the objective 72 propagates in the main beam path 67 in the opposite direction to the laser beams 63, is separated from the laser light by the beam splitter 66 and is focused by a lens 74 through a pinhole 75 onto a detector 76. A filter 77 additionally blocks interfering stray light.

To ensure laser safety, the laser scanning unit 60 comprises a shutter 78 arranged at the exit port 68, which prevents laser light from escaping from the (otherwise closed) laser scanning unit 60 in the closed state. To minimize hazards from escaping laser light, the shutter 78 releases the laser beams 63 only during image acquisition, i.e., when the laser scanning microscope 59 is in a safe operating state for laser scanning. In particular, this operating state requires that the laser scanning microscope 59 has been put into operation by an authorized user with a key switch 79. Further, it must be ensured that the light path in the microscope stand 61 is configured for laser scanning and, particularly, that laser light cannot escape at other locations where there is a risk to the user, for example from an eyepiece (not shown). The light path is configured, for example, with a movable deflection mirror 80 whose position is detected with a sensor 81.

Once the key switch 79 is actuated and the signal from the sensor 81 indicates the correct position of the deflection mirror 80, the output of the AND gate 82 provides a control signal 11 to the series-connected switching elements 3, 4, which connect the shutter 78 to the voltage source 37 so that the shutter 78 opens and releases the beam path.

According to the invention, the switching state of the switching elements 3, 4 is monitored by coupling a monitor signal 13 generated with a signal source 12 at the feed point 14 between the switching elements 3, 4 and by separating the monitor signal 13 with filters 20, 21 at the probe points 16, 17 and detecting it by detector circuits 23, the output signals of which are monitored for consistency by a comparator 27. Insofar as a deviation of the switching states of the switching elements 3, 4 is detected, the laser scanning microscope 59 is set to a safe state by disconnecting the lasers from the voltage source 37 with the switching element 35 acting as an emergency shutdown and thus switching them off.

Optional blocking filters between the switching elements 3, 4 and the voltage source 37 on the one hand and the switching elements 3, 4 and the shutter 79 on the other hand are omitted in the illustration for the sake of clarity.

### LIST OF REFERENCE SIGNS

1 Interrupter circuit
2 Circuit
3 First switching element
4 Second switching element
5 Diagnostic circuit
6 Terminal
7 Switch/Button
8 Relay/Contactor
9 Semiconductor switch
10 Trigger
11 Control signal
12 Signal source
13 Monitor signal
14 Feed point
15 Coupler
16 First probe point
17 Second probe point
18 First probe signal
19 Second probe signal
20 First filter
21 Second filter
22 Useful signal
23 Detector circuit
24 First status signal
25 Second status signal
26 Blocking filter
27 Comparator
28 Control signal
29 Error signal
30 OR gate
31 Aggregated error signal
32 Laser
33 Supply circuit
34 Solid state relay
35 Switching element
36 Consistency tester
37 Voltage source
38 Switching element
39 Switching element
40 Second feed point
41 Third feed point
42 Monitor signal
43 Carrier signal
44 Encoder A
45 Encoder B
46 Identifier A
47 Identifier B
48 Third filter
49 Decoder A
50 Decoder B
51 Status signal
52 Period
53 Rising edge
54 First time window
55 Second time window
56 Track
57 Track
58 Track
59 Laser scanning microscope
60 Laser scanning unit
61 Microscope stand
62 Sample
63 Laser beam
64 Mirror
65 Beam splitter
66 Beam splitter
67 Main beam path
68 Exit port
69 Light port
70 Scan lens
71 Tube lens
72 Objective
73 Scanner
74 Lens
75 Pinhole
76 Detector
77 Filter
78 Shutter
79 Key switch
80 Deflection mirror
81 Sensor
82 AND gate

1.-12. (canceled)

13. An interrupter circuit for interrupting a useful signal in an electrical circuit comprising at least a first and a second switching element connected in series and a diagnostic circuit for monitoring the switching states of the switching elements comprising
a signal source which is configured to generate a monitor signal which can be coupled into the circuit at a feed point between the switching elements connected in series;
a first probe point and a second probe point in the circuit, so that the first switching element is located between the first probe point and the feed point and the second switching element is located between the second probe point and the feed point in the circuit;
a first filter configured to separate the monitor signal from a probe signal tapped at the first probe point, and a second filter configured to separate the monitor signal from a probe signal tapped at the second probe point; and
detector circuits arranged downstream of the first filter and the second filter, which are configured to extract the monitor signal from the respective probe signal and to generate a respective status signal which represents the switching status of the respective switching element.

14. The interrupter circuit according to claim 13, wherein the switching elements are selected from the group of mechanically or magnetically operated switches or pushbuttons, mechanical relays or contactors, transistors, field-effect transistors, photo transistors, photo-thyristors, photo-triacs, optocouplers, semiconductor relays or Hall sensors.

15. The interrupter circuit according to claim 13, wherein the monitor signal is a periodic signal with an amplitude which is not more than 10% of an amplitude of the useful signal.

16. The interrupter circuit according to claim 13, wherein the monitor signal is a periodic signal with an amplitude which is not more than 5% of an amplitude of the useful signal.

17. The interrupter circuit according to claim 13, wherein the monitor signal is a periodic signal with an amplitude which is not more than 2% of an amplitude of the useful signal.

18. The interrupter circuit according to claim 15, wherein a frequency of the monitor signal is at least a factor of 10 higher than an upper limit frequency or at least a factor of 10 lower than a lower limit frequency of the useful signal.

19. The interrupter circuit according to claim 13, wherein the interrupter circuit comprises a respective blocking filter arranged between terminals of the circuit and the probe points, wherein the blocking filter is configured to suppress the monitor signal by at least 10 dB.

20. The interrupter circuit according to claim 13, wherein the interrupter circuit comprises a respective blocking filter arranged between terminals of the circuit and the probe points, wherein the blocking filter is configured to suppress the monitor signal by at least 20 dB.

21. The interrupter circuit according to claim 13, wherein the interrupter circuit comprises a respective blocking filter arranged between terminals of the circuit and the probe points, wherein the blocking filter is configured to suppress the monitor signal by at least 30 dB.

22. The interrupter circuit according to claim 15, wherein the monitor signal is amplitude-, frequency- or phase-modulated.

23. The interrupter circuit according to claim 22, wherein the monitor signal is adapted to transmit data from the feed point to the probe points.

24. The interrupter circuit according to claim 13, wherein the diagnostic circuit comprises a comparator which is configured to compare the status signal of one of the switching elements with a control signal of the same switching element.

25. The interrupter circuit according to claim 24, wherein the interrupter circuit comprises at least one further switching element which is connected in series with the first and the second switching element and is configured to interrupt the circuit if the comparator detects a deviation of the status signal of the first or the second switching element from the control signal of the same switching element.

26. The interrupter circuit according to claim 13, wherein in case the switching elements receive a common control signal, the diagnostic circuit comprises a comparator which is configured to compare the status signal of the first switching element with the status signal of the second switching element.

27. The interrupter circuit according to claim 26, wherein the interrupter circuit comprises at least one further switching element which is connected in series with the first and the second switching element and is configured to interrupt the circuit if the comparator detects a deviation between the status signals of the switching elements.

28. The interrupter circuit according to claim 13, wherein the interrupter circuit comprises at least one further switching element connected in series with the first and the second switching element, and wherein between the switching elements at least one further feed point for feeding in at least one further monitor signal and at least one further probe point for tapping at least one further probe signal are arranged, the monitor signals being distinguishable from one another.

29. A laser scanning microscope comprising a laser safety device, wherein the laser safety device comprises an interrupter circuit according to claim 13.

30. A method for monitoring the switching states of a first and a second switching element connected in series for interrupting a useful signal in an electrical circuit comprising the steps of:
generating a monitor signal and coupling the monitor signal into the circuit at a feed point between the two switching elements connected in series;
tapping of probe signals from the circuit at a first probe point and a second probe point, the probe points being arranged in such a way that the first switching element is located in the circuit between the first probe point and the feed point and the second switching element is located between the second probe point and the feed point;
separating the monitor signal from the probe signals by means of a respective filter for each of the probe signals; and
generating a first status signal representing the switching state of the first switching element and a second status signal representing the switching state of the second switching element from the respective separated monitor signal.
